(19) United States
(12) Patent Application Publication
(10) Pub. No.: US 2015/0092342 A1
(43) Pub. Date: Apr. 2, 2015

(54) ELECTRONIC DEVICE

(71) Applicant: HONG FU JIN PRECISION INDUSTRY (ShenZhen) CO., LTD., Shenzhen (CN)

(72) Inventors: WEN-TANG PENG, New Taipei (TW); XIAO-ZHENG LI, Shenzhen (CN)

(73) Assignee: HON HAI PRECISION INDUSTRY CO., LTD., New Taipei (TW)

(21) Appl. No.: 14/499,443

(22) Filed: Sep. 29, 2014

(30) Foreign Application Priority Data
Sep. 27, 2013 (CN) 201310447972.0

(51) Int. Cl. H05K 7/20; F04D 19/00; F04D 29/52; H05K 7/14

(52) U.S. Cl. CPC H05K 7/20736; H05K 7/1488; F04D 19/002; F04D 29/522
USPC 361/679.48; 415/220

(57) ABSTRACT

An electronic device includes a chassis, a circuit board, and a fan module. The chassis includes a side plate defining an opening. The circuit board is located inside the chassis and includes a first connector. The fan module includes a fan and a cage enclosing the fan. The fan includes a second connector. The cage includes a first receiving member. Two latch portions are formed on opposite ends of the first receiving member. Each latch portion includes at least one block. The latch portions are deformable to allow the fan module to be placed inside the chassis through the opening. The at least one block abutting against an inner surface of the side plate. The second connector of the fan is electrically coupled to the first connector of the circuit board.

### FIELD

The present disclosure relates to an electronic device with a fan module.

### BACKGROUND

An electronic device, such as a computer or a server, needs a plurality of fans to dissipate heat for electronic components of the electronic device. The fans need to be replaced when broken.

### BRIEF DESCRIPTION OF THE DRAWINGS

Implementations of the present technology will now be described, by way of example only, with reference to the attached figures.

FIG. 1 is an exploded, isometric view of an exemplary embodiment of an electronic device, wherein the electronic device comprises a fan module.

FIG. 2 is an inverted view of the fan module of FIG. 1.

FIG. 3 is an assembled, isometric view of the fan module FIG. 2.

FIG. 4 is an assembled, isometric view of the electronic device of FIG. 1.

FIG. 5 is a cross-sectional view taken along line V-V of FIG. 4.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

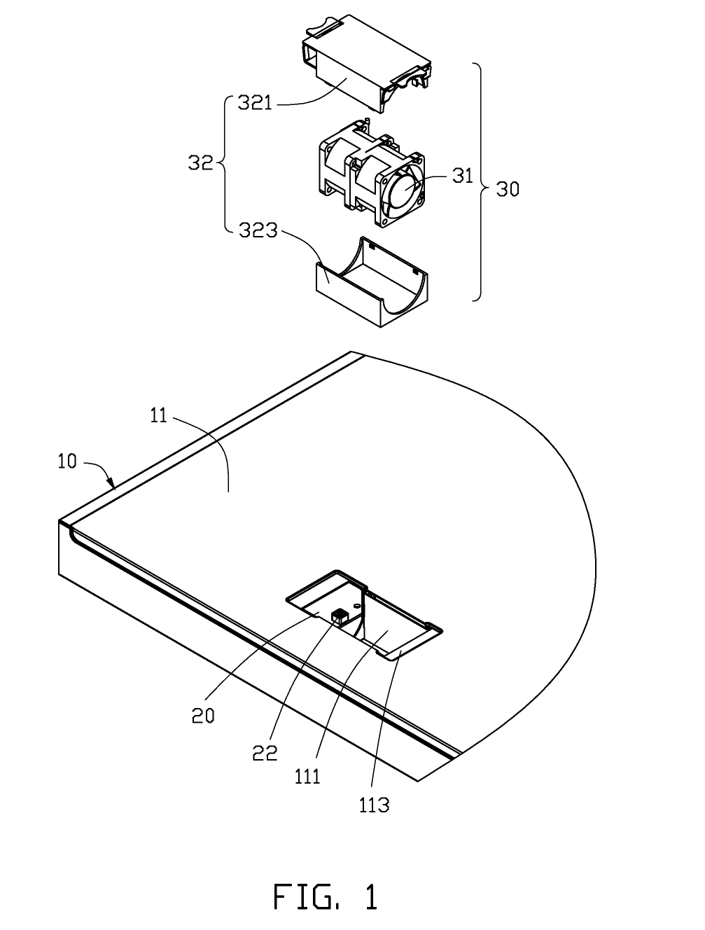

FIG. 1 illustrates an exemplary embodiment of an electronic device. The electronic device comprises a chassis 10, a circuit board 20 located inside the chassis 10, and a fan module 30. In the embodiment, the electronic device is a server.

The chassis 10 comprises a side plate 11. The side plate 11 defines an opening 111 and two recesses 113 located at opposite sides of the opening 111. The side plate 11 can be located at a top of the chassis 10; the side plate also can be located at a bottom of the chassis 10.

The circuit board 20 comprises a connector 22. The connector 22 aligns with the opening 111.

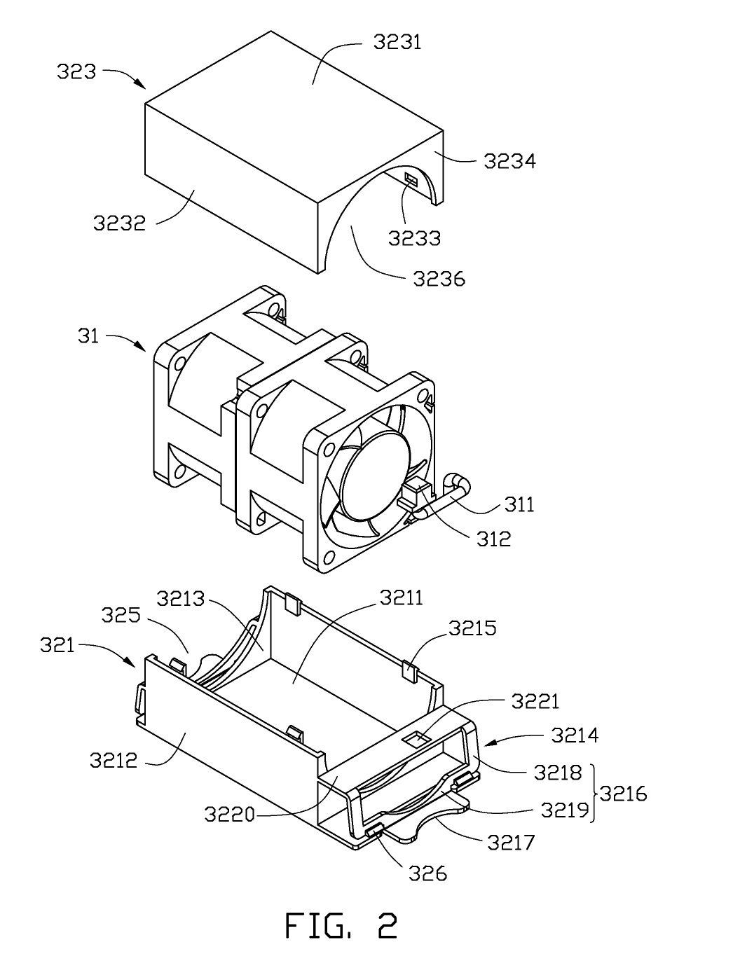

FIGS. 1 and 2 illustrate the fan module 30 comprising a fan 31 and a cage 32 for enclosing the fan 31. A cable 311 is electrically coupled to the fan 31. A connector 312 is electrically coupled to a distal end of the cable 311. The cage 32 comprises a first receiving member 321 and a second receiving member 323. The second receiving member 323 can engage with the first receiving member 321.

The first receiving member 321 comprises a base plate 3211, two side plates 3212 substantially perpendicularly extending from opposite sides of the base plate 3211, two end plates 3213 substantially perpendicularly extending from opposite ends of the base plate 3211, and two resilient latch portions 3214. Two hooks 3215 extend from an edge of each side plate 3212 away from the base plate 3211. Each end plate 3213 defines a semicircular vent 325, to allow airflow of the fan 31 to flow through. Each latch portion 3214 comprises a substantially U-shaped resilient portion 3216 and a handle 3217. The resilient portion 3216 comprises two parallel resilient arms 3218 and a connection element 3219 coupled to the resilient arms 3218. Two wedge-shaped blocks 326 extend from the connection element 3219. The handle 3217 extends from the connection element 3219, located between the blocks 326. The resilient arms 3218 of one of the latch portions 3214 are coupled to an outer surface one of the end plates 3213. An extension plate 3220 substantially perpendicularly extends from an outer surface of the other end plate 3213. The resilient arms 3218 of the other latch portion 3214 are coupled to opposite ends of an edge of the extension plate 3220 away from the other end plate 3213. The extension plate 3220 is parallel to the base plate 3211. The extension plate 3220 defines a mounting hole 3221.

The second receiving member 323 comprises a base wall 3231, two sidewalls 3232 substantially perpendicularly extending from opposite sides of the base wall 3231, and two end walls 3234 substantially perpendicularly extending from opposite ends of the base wall 3231. Each sidewall 3232 defines two latch holes 3233. Each end wall 3234 defines a semicircular vent 3236, to allow airflow of the fan 31 to flow through.

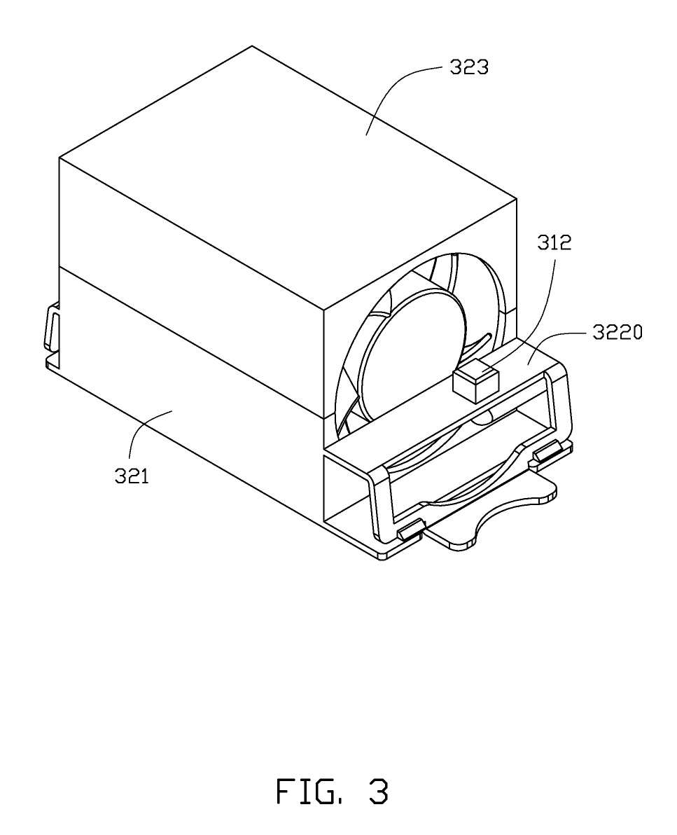

FIG. 3 illustrates the assembly of the fan module 30. The fan 31 is placed into the first receiving member 321. The hooks 3215 of the first receiving member 321 engage in the latch holes 3233 of the second receiving member 323. Therefore, the first receiving member 321 is fastened to the second receiving member 323, the fan 31 is enclosed by the first receiving member 321 and the second receiving member 323. The connector 312 of the fan 31 engages in the mounting hole 3221.

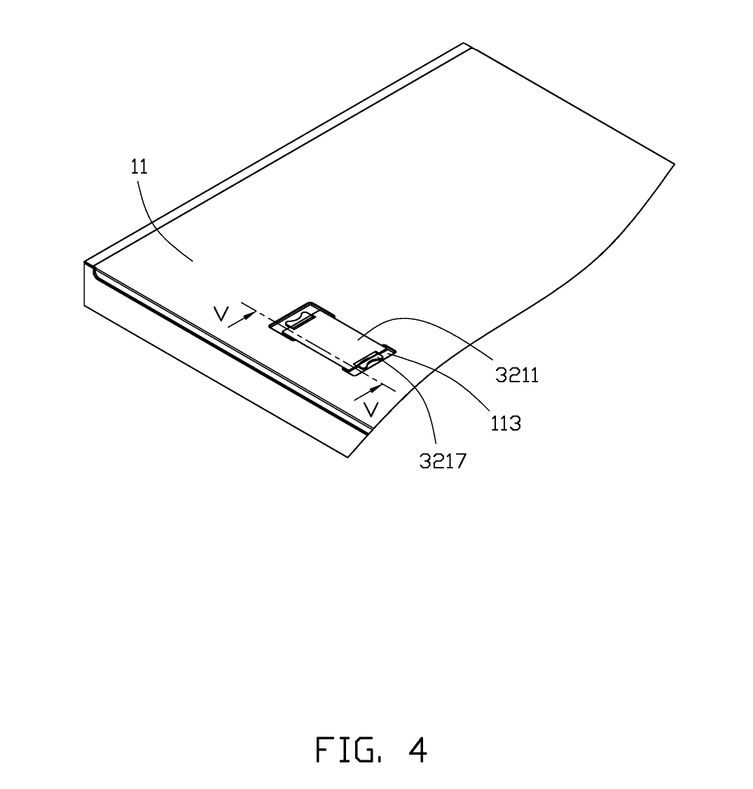

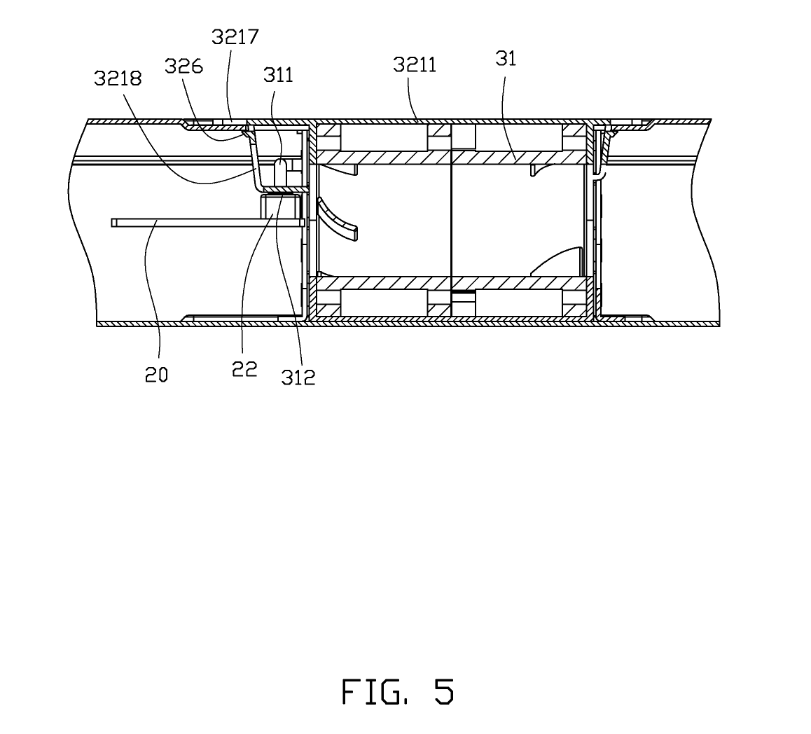

FIGS. 4 and 5 illustrate the assembly of the electronic device. The fan module 30 is placed inside the chassis 10 through the opening 111. The resilient arms 3218 abut against a sidewall bounding the opening 111, and are deformed. After the resilient arms 3218 extend through the opening 111, the resilient arms 3218 are restored. The blocks 326 abut against an inner surface of the side plate 11. The handles 3217 are received in the recesses 113. The connector 312 of the fan 31 is electrically coupled to the connector 22 of the circuit board 20.

To detach the fan module 30, the handles 3217 are pulled toward each other. The resilient arms 3218 are deformed, to allow the blocks 326 to disengage from the side plate 11. The fan module 30 can be taken outside the chassis 10 through the opening 111.

The embodiments shown and described above are only examples. Even though numerous characteristics and advantages of the present technology have been set forth in the foregoing description, together with details of the structure and function of the present disclosure, the disclosure is illustrative only, and changes may be made in the details, including in matters of shape, size and arrangement of the parts within the principles of the present disclosure up to, and including, the full extent established by the broad general meaning of the terms used in the claims.

What is claimed is:

1. An electronic device, comprising:
a chassis comprising a side plate, the side plate defining an opening;
a circuit board located inside the chassis and comprising a first connector; and
a fan module comprising a fan and a cage enclosing the fan, the fan comprising a second connector, the cage comprising a first receiving member, two latch portions formed on opposite ends of the first receiving member, each latch portion comprising at least one block;
wherein, the latch portions are deformable to allow the fan module to be placed inside the chassis through the opening, the at least one block abutting against an inner surface of the side plate, the second connector of the fan is electrically coupled to the first connector of the circuit board.

2. The electronic device of claim 1, wherein each latch portion comprises a resilient portion and a handle, the resilient portion comprises two parallel resilient arms and a connection element coupled to the resilient arms, the handle and the at least one block extending from the connection element.

3. The electronic device of claim 2, wherein the side plate defines two recesses located at opposite sides of the opening, the handles of the latch portions are received in the recesses.

4. The electronic device of claim 2, wherein the first receiving member comprises a base plate, two side plates substantially perpendicularly extending from opposite sides of the base plate, and two end plates substantially perpendicularly extending from opposite ends of the base plate, each end plate defines a vent.

5. The electronic device of claim 4, wherein the resilient arms of one of the latch portions are coupled to an outer surface of one of the end plates, an extension plate substantially perpendicularly extends from an outer surface of the other end plate, the resilient arms of the other latch portion are coupled to opposite ends of an edge of the extension plate away from the other end plate.

6. The electronic device of claim 5, wherein the extension plate is parallel to the base plate, the extension plate defines a mounting hole, the second connector of the fan engages in the mounting hole.

7. The electronic device of claim 4, wherein the cage further comprises a second receiving member for engaging with the first receiving member, the fan is enclosed by the first receiving member and the second receiving member.

8. The electronic device of claim 7, wherein two hooks extend from an edge of each side plate of the first receiving member away from the base plate, the second receiving member comprises a base wall and two sidewalls substantially perpendicularly extending from opposite sides of the base wall, each sidewall defines two latch holes, the hooks engage in the latch holes.

9. The electronic device of claim 8, wherein the second receiving member further comprises two end walls substantially perpendicularly extending from opposite ends of the base wall, each end wall defines a vent.

10. An electronic device, comprising:
a chassis comprising a side plate, the side plate defining an opening; and
a fan module comprising a cage, the cage comprising a first receiving member and a second receiving member, the first receiving member and the second receiving member configured to enclose a fan, two latch portions formed on opposite ends of the first receiving member, each latch portion comprising at least one block;
wherein, the latch portions are deformable to allow the fan module to be placed inside the chassis through the opening, the at least one block abutting against an inner surface of the side plate.

11. The electronic device of claim 10, wherein each latch portion comprises a resilient portion and a handle, the resilient portion comprises two parallel resilient arms and a connection element coupled to the resilient arms, the handle and the at least one block extending from the connection element.

12. The electronic device of claim 11, wherein the side plate defines two recesses located at opposite sides of the opening, the handles of the latch portions are received in the recesses.

13. The electronic device of claim 11, wherein the first receiving member comprises a base plate, two side plates substantially perpendicularly extending from opposite sides of the base plate, and two end plates substantially perpendicularly extending from opposite ends of the base plate, each end plate defines a vent.

14. The electronic device of claim 13, wherein the resilient arms of one of the latch portions are coupled to an outer surface one of the end plates, an extension plate substantially perpendicularly extends from an outer surface of the other end plate, the resilient arms of the other latch portion are coupled to opposite ends of an edge of the extension plate away from the other end plate.

15. The electronic device of claim 14, wherein the extension plate is parallel to the base plate.

16. The electronic device of claim 13, wherein two hooks extend from an edge of each side plate of the first receiving member away from the base plate, the second receiving member comprises a base wall and two sidewalls substantially perpendicularly extending from opposite sides of the base wall, each sidewall defines two latch holes, the hooks engage in the latch holes.

17. The electronic device of claim 16, wherein the second receiving member further comprises two end walls substantially perpendicularly extending from opposite ends of the base wall, each end wall defines a vent.

18. A fan module, comprising:
a fan comprising a connector;
a first receiving member, two deformable latch portions formed on opposite ends of the first receiving member, each latch portion comprising at least one block, the first receiving member defining a mounting hole for the connector to extend through; and
a second receiving member configured to engage with the first receiving member, the fan enclosed by the first receiving member and the second receiving member.

19. The fan module of claim 18, wherein the first engaging member comprises a base plate, two side plates substantially perpendicularly extending from opposite sides of the base plate, and two end plates substantially perpendicularly extending from opposite ends of the base plate, two hook are formed on each side plate, the second receiving member comprises a base wall, two sidewalls substantially perpendicularly extending from opposite sides of the base wall, and two end walls substantially perpendicularly extending from opposite ends of the base wall, each sidewall defines two latch holes, the hooks engage in the latch holes.

20. The fan module of claim 19, wherein one of the latch portions extends from an outer surface of one of the end plates, an extension plate substantially perpendicularly extends from an outer surface of the other end plate, the other latch portion extends from an edge of the extension plate away from the other end plate.
